(19) United States
(12) Patent Application Publication
(10) Pub. No.: US 2005/0142708 A1
(43) Pub. Date: Jun. 30, 2005

(54) Method for forming polycrystalline silicon film

(76) Inventors: Kyoung Seok Son, Seoul (KR); Ho Nyeon Lee, Kyoungki-do (KR); Myung Kwan Ryu, Kyoungki-do (KR); Jae Chul Park, Seoul (KR); Eok Su Kim, Seoul (KR); Jun Ho Lee, Kyoungki-do (KR); Se Yeoul Kwon, Seoul (KR)

Correspondence Address: LADAS & PARRY LLP, 224 SOUTH MICHIGAN AVENUE, SUITE 1200, CHICAGO, IL, 60604, US

(21) Appl. No.: 10/930,011

(22) Filed: Aug. 30, 2004

(30) Foreign Application Priority Data
Dec. 30, 2003 (KR) 2003-100230

(51) Int. Cl. H01L 21/00; H01L 21/84

(52) U.S. Cl. 438/166

(57) ABSTRACT

Disclosed herein is a method for forming a polycrystalline (poly-Si) film by the crystallization of an amorphous silicon film using laser light irradiation. The disclosed method comprises the steps of: sequentially depositing a buffer film and an amorphous silicon film on a glass substrate; depositing a metal film having laser light reflection function on the back side of the glass substrate; and irradiating the front side of the amorphous silicon film with laser light to crystallize the amorphous silicon film. In the laser light irradiation step, the irradiated laser light is absorbed into the amorphous silicon film, and a portion of the absorbed laser light is transmitted through the amorphous silicon film. The transmitted light is reflected from the metal film and absorbed into the amorphous silicon film again, thus crystallizing the amorphous silicon film twice over. According to the present invention, the amorphous silicon film is crystallized twice over so that a polycrystalline film having very large grains can be formed.

### BACKGROUND OF THE INVENTION

1. Field of the Invention

The present invention relates to a method for fabricating a liquid crystal display, and more particularly, to a method for forming a polycrystalline silicon film for polycrystalline silicon thin-film transistors.

2. Description of the Prior Art

A thin film transistor (hereinafter, referred to as TFT), which is used as a switching device in liquid crystal displays or organic electroluminescent displays, is the most important element in the performance of such displays. Mobility or leakage current, which is a standard for the evaluation of the TFT's performance, greatly depends on the state or structure of an active layer through which an electric charge carrier moves. Namely, this characteristic greatly depends on the state or structure of a silicon thin film which is a material for the active layer. In liquid crystal displays which are currently commercially available, the active layer in TFT is mostly made of amorphous silicon (hereinafter, referred to as a-Si).

However, an a-Si TFT which uses a-Si as the active layer has a very low mobility of about 0.5 cm²/Vs, and thus, has a limitation in making all switching devices included in the liquid crystal display. In other words, although a driving device for peripheral circuits of the liquid crystal display needs to be operated at very fast speed, the a-Si TFT cannot satisfy an operation speed required in the driving device for peripheral circuits, and thus, it is substantially difficult to realize the drive device for peripheral circuits with the a-Si TFT.

Meanwhile, a poly-Si TFT which uses polycrystalline silicon (hereinafter, referred to as poly-Si) as the active layer has a high mobility of several tens to several hundreds cm²/Vs, and thus, can show high driving speed that can cope with the driving device for peripheral circuits. For this reason, if a poly-Si film is formed on a glass substrate, a pixel-switching device and also driving parts for peripheral circuits can be realized. Furthermore, a separate module process necessary for the formation of peripheral circuits will not be required, and the driving parts for peripheral circuits can be formed simultaneously with pixel regions. This will result in a reduction in costs of the driving parts for peripheral circuits.

Moreover, the poly-Si TFT can be made to a smaller size than that of the a-Si TFT due to its high mobility, and the driving device for peripheral circuits and the switching device for pixel regions can be simultaneously formed by an integrated process. Thus, the poly-Si TFT makes easier the realization of fine-linewidth features, and is very advantageous in obtaining high resolution which is difficult to realize in an a-Si TFT-LCD.

In addition, the poly-Si TFT has a characteristic of high current, and thus, is suitable as a driving device for an organic electroluminescent display that is the next generation flat panel display.

Accordingly, researches on a fabricating method of poly-Si TFTs, where a poly-Si film is formed on a glass film to fabricate a TFT, are being actively conducted.

An example of the method of forming the poly-Si film on the glass substrate includes a method comprising the steps of depositing an a-Si film on the glass substrate, and thermally treating the deposited a-Si film to crystallize the a-Si film. In this method, however, the deformation of the glass substrate occurs at a high temperature above 600° C., thereby causing reductions in reliability and yield.

Thus, as a method allowing crystallization of only the a-Si film without causing thermal damages to the glass substrate, a low-temperature polycrystallization method using an excimer laser was proposed. This method can be divided into the following two categories. One method is a conventional excimer laser annealing (hereinafter, referred to as ELA) method with no use of a mask, and the other method is a sequential lateral solidification (hereinafter, referred to as SLS) method where regions irradiated with laser light are controlled with a mask.

In all of such two methods, the a-Si film is deposited on the glass substrate in a state where a buffer film serving to prevent impurities in the glass substrate from flowing into a silicon layer was deposited on the glass substrate. Then, a thermal treatment process is conducted to remove hydrogen from the a-Si film, after which the a-Si film is exposed to the eximer laser for a very short time, so that the a-Si film is transformed into a poly-Si film via a liquid phase without causing deformation of the glass substrate.

However, all of the two methods have a limitation in increasing the size of grains.

In other words, in the case of the conventional ELA method, the grain size is below 0.1 μm at which mobility is insufficient to integrate the driving circuits.

In the SLS method, the crystallization of the a-Si film starts from the edge of the irradiated region and is induced to the inside thereof. With respect to the fact that the crystallization finally occurs at the central portion of the irradiated region, if the temperature of the central portion during the crystallization is lowered to its melting point, nucleation will occur to make it impossible to obtain large grains. As a result, the polycrystalline silicon film formed according to the prior SLS method has the greatest possible lateral growth length of 4 μm, and thus, it is difficult to actually apply this silicon film to a TFT for the peripheral circuits.

### SUMMARY OF THE INVENTION

Accordingly, the present invention has been made to solve the above-mentioned problems occurring in the prior art, and an object of the present invention is to provide a method for forming a poly-Si film, which can maximize grain size.

Another object of the present invention is to provide a method for forming a poly-Si film, which can maximize grain size to make it possible to improve the performance of a poly-Si TFT.

Still another object of the present invention is to provide a method for forming a poly-Si film, which can improve the performance of a poly-Si TFT to allow integration of a pixel switching device and a peripheral circuit-driving device on a single substrate.

To achieve the above object, in one embodiment, the present invention provides a method for forming a poly-Si film by the crystallization of an a-Si film using laser light irradiation, the method comprising the steps of: sequentially depositing a buffer film and an a-Si film on a glass substrate; depositing a metal film having laser light reflection function on the back side of the glass substrate; and irradiating the front side of the glass substrate with laser light, in which the irradiated laser light is absorbed into the amorphous silicon film, and a portion of the absorbed laser light is transmitted through the amorphous silicon film, reflected from the metal film, and absorbed into the amorphous silicon film again, thus crystallizing the amorphous silicon film twice over.

In the inventive method, the metal film is either a single layer film selected from Mo, Al, AlNd, Cr, Cu, MoW, W, Ta and Ti layers, or a layered film of two or more of the layers.

In another embodiment, the present invention provides a method for forming a poly-Si film by the crystallization of an a-Si film using laser light irradiation, the method comprising the steps of: forming a gate electrode having laser light reflection function on a glass substrate; depositing a gate insulating film on the substrate so as to cover the gate electrode; depositing an a-Si film on the gate insulating film; and irradiating the front side of the a-Si film with laser light, in which the irradiated laser light is absorbed into the amorphous silicon film, and a portion of the absorbed laser light is transmitted through the amorphous silicon film, reflected from the metal film, and absorbed into the amorphous silicon film again, thus crystallizing the amorphous silicon film twice over.

### BRIEF DESCRIPTION OF THE DRAWINGS

The above and other objects, features and advantages of the present invention will be more apparent from the following detailed description taken in conjunction with the accompanying drawings, in which:

FIGS. 1A and 1B are cross-sectional views illustrating a method for forming a polycrystalline silicon film according to an embodiment of the present invention;

FIGS. 2A and 2B are photographs showing the crystallized states of polycrystalline silicon films formed according to prior art and the present invention, respectively; and

FIGS. 3 is a cross-sectional view illustrating a method for forming a polycrystalline silicon film according to another embodiment of the present invention.

### DETAILED DESCRIPTION OF THE PREFERRED EMBODIMENTS

Hereinafter, a preferred embodiment of the present invention will be described in detail with reference to the accompanying drawings.

A technical principle of the present invention will first be described. In conducting a low-temperature crystallization process by excimer laser irradiation, a metal film having high reflectivity is formed on the lower surface of an a-Si film. Thus, in the step of irradiating the a-Si film with laser light, the laser light absorbed into the a-Si film is partially transmitted through the a-Si film, and reflected from the metal film, and then absorbed into the Si film again. Thus, an effect equal to two-step laser irradiation is obtained by one-step laser irradiation, so that the size of grains in a poly-Si film is increased.

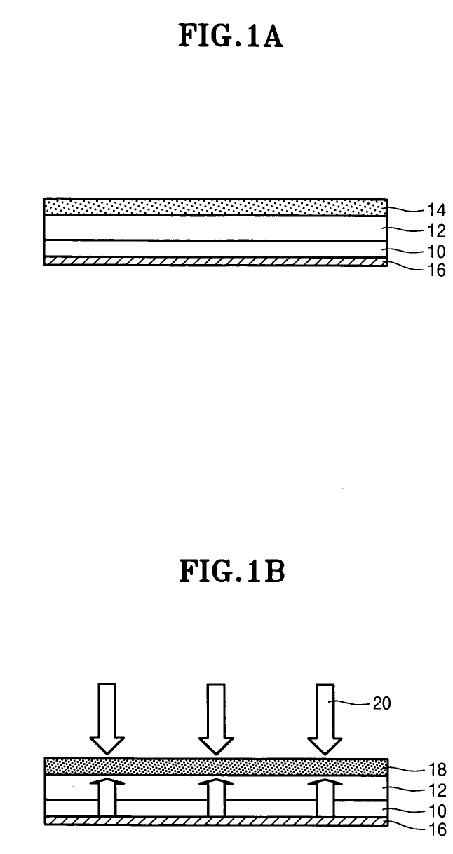

The present invention will now be described in detail with reference to FIGS. 1A and 1B, which are cross-sectional views illustrating a method for forming a poly-Si film according to the present invention. The inventive method to be described below can be applied for the formation of a TFT having a top gate structure.

Referring to FIG. 1A, a buffer film 12 made of a material, such as SiOₓ, SiOₓN_{y} or SiNₓ, is formed on a glass substrate 10, such that unnecessary ions in the glass substrate are prevented from flowing into a poly-Si film, an active layer, in a subsequent thermal treatment process. Then, an a-Si film 14 to be crystallized is deposited on the buffer film 12. Next, to remove hydrogen present in the a-Si film 14, the resulting substrate is subjected to a thermal treatment process at a temperature above 400° C.

Thereafter, a metal film 16 having laser light reflection function is deposited on the back side of the glass substrate before performing a crystallization process of the a-Si film by laser light irradiation. The metal film 16 is made of either a single layer film selected from Mo, Al, AlNd, Cr, Cu, MoW, Ta and Ti layers having excellent reflectivity, or a layered film of two or more of such metal layers.

Referring to FIG. 1B, the front side of the a-Si film is irradiated with laser light 20 according to the conventional ELA method or the SLS method, so that the a-Si film is crystallized to form a poly-Si film 18. In this laser beam irradiation process, a portion of the irradiated laser light 20 is absorbed into, and transmitted through the a-Si film. The transmitted light reaches the glass substrate 10 via the buffer film 12, and is reflected from the metal film 16 formed on the back side of the glass substrate 10. The reflected light is sequentially passed through the glass substrate 10 and the buffer film 12, and absorbed into the a-Si film again. Thus, an effect equal to two-step laser irradiation is obtained by the one-step laser irradiation, so that the size of grains in the crystallized poly-Si film 18 is far greater than that of the prior art.

Concretely speaking, in the prior art, a portion of the Si film, which was melted into a liquid phase by laser light absorption, starts to coagulate from the interface with a portion of the a-Si film, which was not irradiated with laser light. The crystallization is induced to the central portion of the irradiated region. However, during this coagulation, the temperature of the central portion is rapidly lowered due to heat transfer caused by the temperature difference between the melted Si film and the lower film or the substrate. Thus, before completion of the induced crystallization, nucleation occurs to produce small grains. For this reason, in the prior art, the interval between the irradiated regions needs to be reduced such that the induced crystallization is completed before the nucleation occurs. The size of the irradiated region which is generally used is about 5 μm, and the grain size after completion of the crystallization is at a maximum of 3.5-4 μm.

On the other hand, in the present invention, the transmitted laser light 20 is reflected from the metal film 16 and absorbed into the Si film again, so that a reduction in temperature of the melted Si film is inhibited to make it possible to maintain the melted state of the Si film for an extended period of time as compared to that in the prior art. Thus, the growth time of grains is increased, so that the size of grains in the resulting poly-Si film 18 is increased as compared to that of the prior art. For example, if laser light irradiation is performed using a slit mask pattern having an interval between laser irradiation regions of about 10 μm, the size of grains in the resulting poly-Si film 18 will be about two times as large as that of the prior art.

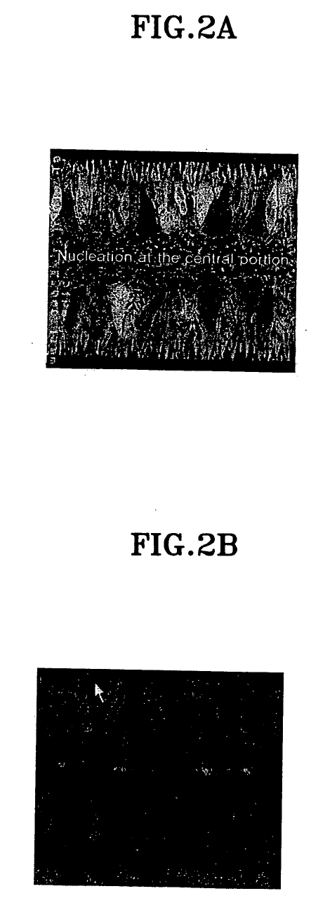

FIGS. 2A and 2B are photographs showing the crystallized states of poly-Si films formed according to the prior art and the present invention, respectively. As shown in FIG. 2A, the size of grains in the poly-Si film formed according to the prior art is not large due to the nucleation at the central portion. However, as shown in FIG. 2B, the size of grains in the poly-Si film formed according to the present invention is relatively large because an effect equal to two-step laser irradiation is achieved by the one-step laser irradiation.

As a result, in the present invention, the poly-Si film 18 having large grains can be very easily formed by forming the metal film 16 having laser light reflection function on the back side of the a-Si film 14 (strictly speaking, the back side of the glass substrate 10).

Although not shown in the figures, the metal film on the back side of the glass substrate is then removed. Next, conventional process for fabricating a TFT, including processes for the formation of an active pattern, the deposition of a gate insulating film, the formation of a gate, ion implantation, the formation of an insulating film, the formation of a contact hole, and the formation of source/drain regions, are sequentially performed to form a poly-Si TFT in a suitable place of the glass substrate. Then, a process for the formation of a pixel electrode is performed to form an array substrate. Thereafter, the array substrate is assembled with a color filter substrate fabricated by a separate process, while sandwiching a liquid crystal layer between the two substrates.

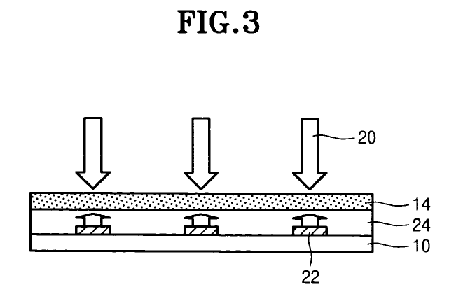

Hereinafter, another embodiment of the present invention will be described with reference to FIG. 3 which is a cross-sectional view illustrating a method for forming a poly-Si film according to another embodiment of the present invention. While the former embodiment can be applied to the formation of a TFT having a top gate structure, this embodiment can be applied to the formation of a TFT having a bottom gate electrode.

A gate electrode 22 is first formed on a glass substrate 10, after which a gate insulating film 24 is formed on the front side of the substrate 10. Then, an a-Si film 14 to be crystallized is deposited on the gate insulating film 24. Next, the a-Si film 14 is irradiated with patterned laser light 20 by means of a mask having a slit mask pattern.

In this laser light irradiation process, the patterned laser 20 is absorbed into, and then transmitted through the a-Si film 12. The transmitted laser light is reflected from the gate electrode 22 and absorbed into the a-Si film 14 again. Thus, similarly to the former embodiment, a poly-Si thin film having larger grains than those of the prior art can be obtained.

Thereafter, conventional processes for fabricating a bottom gate TFT are performed, and a pixel electrode is formed, thereby completing the fabrication of an array substrate.

As described above, according to the present invention, the a-Si film is crystallized into a poly-Si film by the low-temperature crystallization method using laser light irradiation. The laser light irradiation is performed after the metal film having laser light reflection function is deposited on the back side of the glass substrate. Thus, the melted state of the Si film can be maintained for an extended period of time to increase the growth time of grains. This allows formation of the poly-Si film having grains of which size is significantly larger than that that in the prior art.

Thus, according to the present invention, the poly-Si film having large grains can be formed, so that an improvement in performance of a poly-Si TFT, such as an increase in electron mobility, can be achieved. This will result in an improvement in performance of liquid crystal display products.

Although a preferred embodiment of the present invention has been described for illustrative purposes, those skilled in the art will appreciate that various modifications, additions and substitutions are possible, without departing from the scope and spirit of the invention as disclosed in the accompanying claims.

1. A method for forming a polycrystalline film by the crystallization of an amorphous silicon film using laser light irradiation, the method comprising the steps of:
sequentially depositing a buffer film and an amorphous silicon film on a glass substrate;
depositing a metal film having laser light reflection function on the back side of the glass substrate; and
irradiating the front side of the amorphous silicon film with laser light, in which the irradiated laser light is absorbed into the amorphous silicon film, and a portion of the absorbed laser light is transmitted through the amorphous silicon film, reflected from the metal film, and absorbed into the amorphous silicon film again, thus crystallizing the amorphous silicon film twice over.

2. The method of claim 1, wherein the metal film is made of either a single layer film selected from Mo, Al, AlNd, Cr, Cu, MoW, W, Ta and Ti layers, or a layered film of two or more of the layers.

3. A method for forming a poly-Si film by the crystallization of an amorphous silicon film using laser light irradiation, the method comprising the steps of:
forming a gate electrode having laser light reflection function on a glass substrate;
depositing a gate insulating film on the substrate so as to cover the gate electrode;
depositing an amorphous silicon film on the gate insulating film; and
irradiating the front side of the a-Si film with laser light, in which the irradiated laser light is absorbed into the amorphous silicon film, and a portion of the absorbed laser light is transmitted through the amorphous silicon film, reflected from the metal film, and absorbed into the amorphous silicon film again, thus crystallizing the amorphous silicon film twice over.
